(19) United States
(12) Patent Application Publication
(10) Pub. No.: US 2012/0327029 A1
(43) Pub. Date: Dec. 27, 2012

(54) TOUCH INPUT SENSING USING OPTICAL RANGING

(75) Inventor: Russel Allyn Martin, Menlo Park, CA (US)

(73) Assignee: QUALCOMM MEMS TECHNOLOGIES, INC., San Diego, CA (US)

(21) Appl. No.: 13/169,322

(22) Filed: Jun. 27, 2011

(51) Int. Cl. G06F 3/042; H01L 31/18; G01C 21/00

(52) U.S. Cl. 345/175; 250/206.1; 438/24; 257/E31.103

(57) ABSTRACT

This disclosure provides systems, methods and apparatus for touch systems. In one aspect, the touch system can include at least one light guide optically coupled to at least one light source and at least one optical detector. The light guide can be configured to transmit light from at least one light source across the surface in at least one direction and to receive at least a portion of the transmitted light reflected in an opposite direction in response to at least one reflecting object on the surface. The touch system also can include a touchscreen transceiver. The touch system can be configured to determine a location of at least one reflecting object on the surface by identifying a position of where the light guide or the touchscreen transceiver receives the reflected light and by determining time-of-flight of the transmitted light and the reflected light.

### TECHNICAL FIELD

This disclosure relates generally to user interface devices, and more specifically, to optical touchscreen devices using optical ranging.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

User interface devices for various electronic devices typically include a display component and an input component. The display component can be based on a number of optical systems such as liquid crystal display (LCD), organic light-emitting diodes (OLED) and IMODs.

### SUMMARY

The systems, methods and devices of the disclosure each have several innovative aspects, no single one of which is solely responsible for the desirable attributes disclosed herein.

One innovative aspect of the subject matter described in this disclosure can be implemented in a touch system. The touch system includes a surface having an area, at least one light source, at least one light guide, and at least one optical detector. The at least one light guide is optically coupled to the at least one light source. The at least one at least one light guide is configured to transmit light from the at least one light source such that the light travels across the surface in at least one direction. The at least one light guide is also configured to receive at least a portion of the transmitted light reflected in an opposite direction to the at least one direction in response to at least one reflecting object on the surface. The at least one optical detector is optically coupled to the at least one light guide and is configured to receive the reflected portion of the light from the at least one light guide. The touch system is configured to determine a location of the at least one reflecting object on the surface by identifying a position where the at least one light guide receives the reflected portion and by determining the time-of-flight of the transmitted light and the reflected portion.

Another innovative aspect described in this disclosure can be implemented in a method for determining a location of at least one reflecting object on a surface. The method includes a touch system with at least one light guide optically coupled to at least one light source and optically coupled to at least one optical detector. Light is transmitted from the at least one light source using the at least one light guide and directed across the surface in at least one direction. At least a portion of the transmitted light reflected from the at least one reflecting object is received with the at least one light guide, in an opposite direction to the at least one direction. The reflected portion of the light is detected using the at least one optical detector. The method further includes determining the location of the at least one reflecting object. Determining the location includes identifying a position where the at least one light guide receives the reflected portion and determining the time-of-flight of the transmitted light and the reflected portion of the light.

Another innovative aspect described in this disclosure can be implemented in a method of fabricating a touch system. The method includes providing a surface having an area, disposing at least one light guide configured to transmit light and receive reflected light, and optically coupling the at least one light guide to at least one light source. The method further includes positioning the at least one light guide near the surface such that the at least one light guide is configured to transmit light from the at least one light source and across the surface in at least one direction, and such that the at least one light guide is configured to receive at least a portion of the transmitted light reflected from at least one reflecting object on the surface. The method further includes optically coupling the at least one light guide to at least one optical detector. The touch system is configured to determine a location of at least one reflecting object on the surface by identifying a position where the at least one light guide receives the reflected portion from the at least one reflecting object and by determining the time-of-flight of the transmitted light and the light reflected from the at least one reflecting object.

Another innovative aspect described in this disclosure can be implemented in a touch system that includes means for emitting light, means for guiding light to both transmit light across a surface and to receive reflected light, means for detecting light, and means for determining locations of reflecting objects on the surface. The means for determining locations identifies positions where the means for guiding light receive light reflected from the reflecting objects. The means for determining locations further determines the time-of-flight of the transmitted light and the light reflected from the reflecting objects.

For some implementations of the touch system and/or the methods described above, the at least one light guide can include a plurality of light guides. Identifying a position can include identifying a position of the light guide receiving the reflected portion. For some implementations, the at least one optical detector can include a plurality of detectors. Identifying a position can include identifying the position of the detector receiving the reflected portion. The surface can have a first edge and a second edge. At least one direction of which the light is transmitted can be substantially parallel to either the first edge or the second edge. The light can be spread across most of the area of the surface. In some implementations, a plurality of light guides can transmit the light along at least two directions. The at least two directions can be opposite each other or substantially perpendicular to each other. In some implementations, a plurality of light guides also can transmit the light in four directions. Some implementations can be configured to determine locations of a plurality of reflecting objects on the surface. The plurality of reflecting objects can lie along a substantially collinear optical path over which the light is transmitted, e.g., along a similar linear optical path in either the first direction or the second direction. In some implementations, at least one lens can be positioned on an end of at least one light guide. Some implementations can include a plurality of light sources and/or a plurality of detectors. In some implementations, the light source can operate at infrared wavelengths.

Another innovative aspect described in this disclosure can be implemented in a touch system that includes a surface having an area and at least one touchscreen transceiver. The touchscreen transceiver is configured to transmit a first optical signal across the surface in a first direction and a second optical signal across the surface in a second direction. The touchscreen transceiver is also configured to receive at least a first portion of the first optical signal reflected in an opposite direction to the first direction and at least a second portion of the second optical signal reflected in an opposite direction to the second direction. The first portion and the second portion are reflected in response to at least one reflecting object on the surface. The touchscreen transceiver is further configured to determine a location of the at least one reflecting object on the surface by identifying a position within the touchscreen transceiver that received the first reflected portion and by determining a time-of-flight measurement of transmitting the first optical signal and receiving the first reflected portion.

Another innovative aspect described in this disclosure can be implemented in a method for determining a location of a reflecting object on a surface. The method includes providing a touch system including at least one touchscreen transceiver, transmitting a first optical signal from the touchscreen transceiver across at least a portion of the surface such that the first optical signal is transmitted in a first direction, transmitting a second optical signal from the touchscreen transceiver across at least a portion of the surface such that the second optical signal is transmitted in a second direction, receiving by the touchscreen transceiver at least a first portion of the first optical signal reflected in an opposite direction to the first direction and at least a second portion of the second optical signal reflected in an opposite direction to the second direction, the first portion and the second portion reflected in response to the reflecting object, and detecting the first reflected portion by the touchscreen transceiver. The method further includes determining the location of the reflecting object by identifying a position within the touchscreen transceiver that received the first reflected portion and by determining a time-of-flight measurement of transmitting the first optical signal and receiving the first reflected portion.

Another innovative aspect described in this disclosure can be implemented in a touch system that includes means for determining a location of at least one reflecting object on a surface. The means for determining a location includes means for emitting an optical signal, means for transmitting an optical signal across the surface such that a first optical signal travels in a first direction and a second optical signal in a second direction. The means for transmitting is configured to receive at least a first portion of the first optical signal reflected in an opposite direction to the first direction and at least a second portion of the second optical signal reflected in an opposite direction to the second direction. The first portion and the second portion are reflected in response to the at least one reflecting object on the surface. The means for determining a location further includes means for detecting an optical signal. The means for determining a location further includes means for processing that is configured to identify a position within the means for transmitting that received the first reflected portion. The means for processing is also configured to determine a time-of-flight measurement of the first transmitted optical signal and the first reflected portion.

For some implementations of the touch system and/or the methods described above utilizing a touchscreen transceiver, the surface can have a first edge and a second edge. The first direction and the second direction of which the optical signals are transmitted can be substantially parallel to either the first edge or the second edge. The optical signal can be spread across most of the surface. The first direction and the second direction can be opposite each other or substantially perpendicular to each other. In some implementations, the touchscreen transceiver also can transmit optical signals in three or four directions. Some implementations can be configured to determine locations of a plurality of reflecting objects on the area of the surface. The plurality of reflecting objects can lie along a substantially collinear optical path over which the first or second optical signal is transmitted, e.g., along a similar linear optical path in either the first direction or the second direction. In some implementations, the location of a second reflecting object can be determined by a position within the touchscreen transceiver that received the second reflected portion and the time-of-flight measurement of transmitting the second optical signal and receiving the second reflected portion. Transmitting a first optical signal and transmitting a second optical signal can occur at substantially the same time.

Some implementations further can include a plurality of display elements. Some implementations further can include a processor that is configured to communicate with the plurality of display elements. The processor can be configured to process image data. Some implementations further can include a memory device that is configured to communicate with the processor. At least one of the display elements can include an interferometric modulator.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIGS. 9A-9D schematically illustrate examples of input touch systems.

FIGS. 10A-10C schematically illustrate examples of input touch systems.

FIGS. 11A and 11B schematically illustrate examples of input touch systems.

FIG. 12 shows an example method for determining a location of at least one reflecting object on a surface.

FIG. 13 shows an example method of fabricating a touch system.

FIG. 14 schematically illustrates an example of an input touch system.

FIG. 15 shows an example method for determining a location of at least one reflecting object on a surface.

FIGS. 16A and 16B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

In some implementations, a display device can be fabricated using a plurality of display elements such as spatial light modulator elements (e.g., interferometric modulators). The display device can be configured to allow, for example, a user to view different options and functionalities. An input device can be used in conjunction with the display device to allow, for example, the user to select an option viewed on the display device screen. Various implementations can involve a touch system configured to determine a location of at least one reflecting object, such as a finger or a stylus, on the surface of the display device by using optical ranging. Optical ranging can provide a measurement of a distance to a target location, for example, by illuminating the target location with light. The touch system can use optical ranging, e.g., time-of-flight, to determine the distance to a reflecting object on the surface of the display device. By determining the distance to the reflecting object, the touch system can determine the user selected option.

Particular implementations of the subject matter described in this disclosure can be implemented to realize one or more of the following potential advantages. For example, in some implementations, a device can distinguish between two touches on the input device even if the touches were lined up along a same vertical or horizontal path. Some other implementations allow the ability to distinguish more than two touches on the input device even if they were lined up along a same vertical or horizontal path. Various implementations also allow simplification of the interconnections of elements within a display device. For example, touch locations can be determined from two sides of the display, which allows a design with a smaller periphery on the other two sides. In other implementations, a display device determines touch locations from a single side of the display and thus enables a design with a smaller periphery on the other three sides.

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage Vₒ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

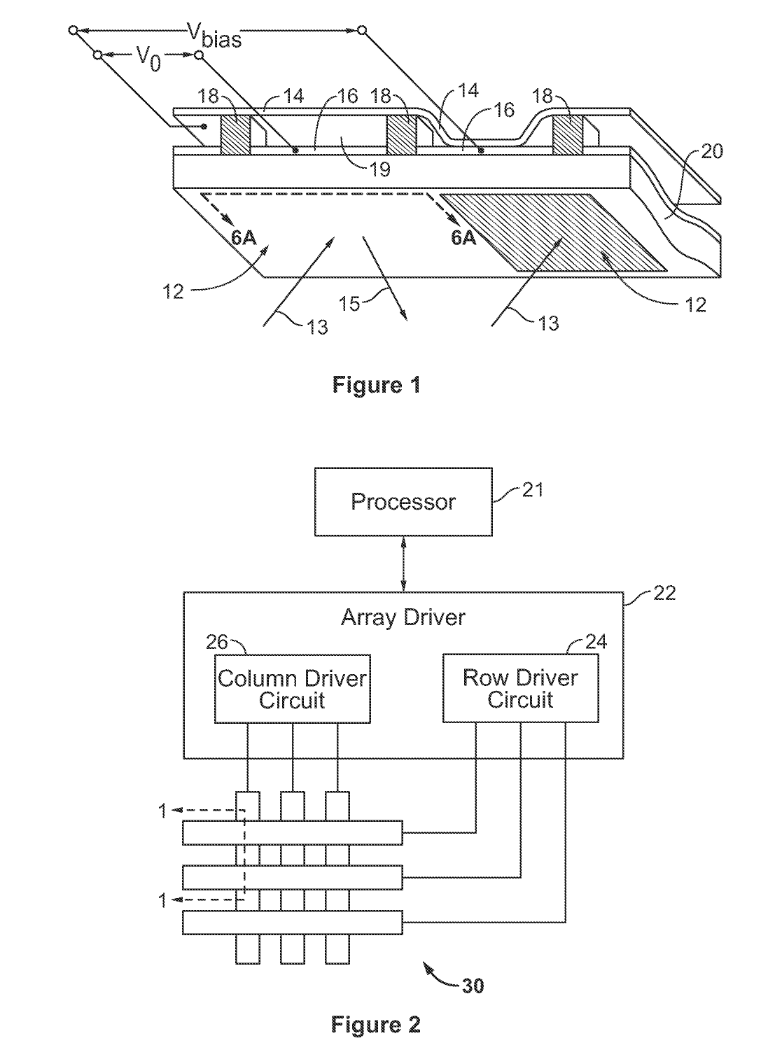

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

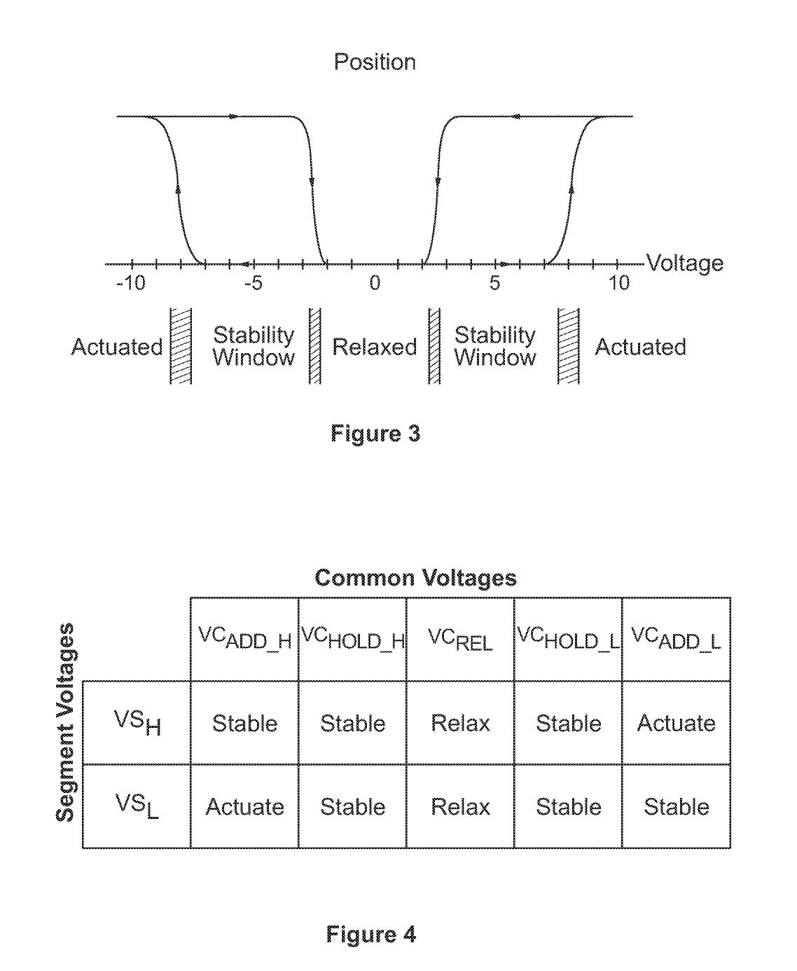

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

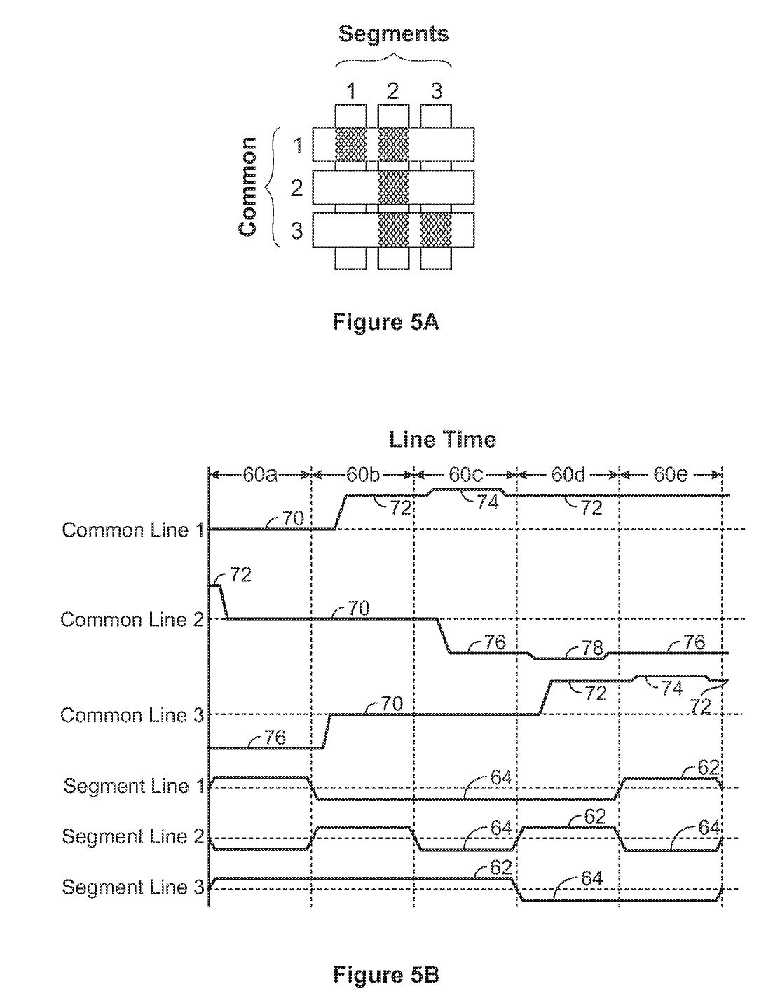

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

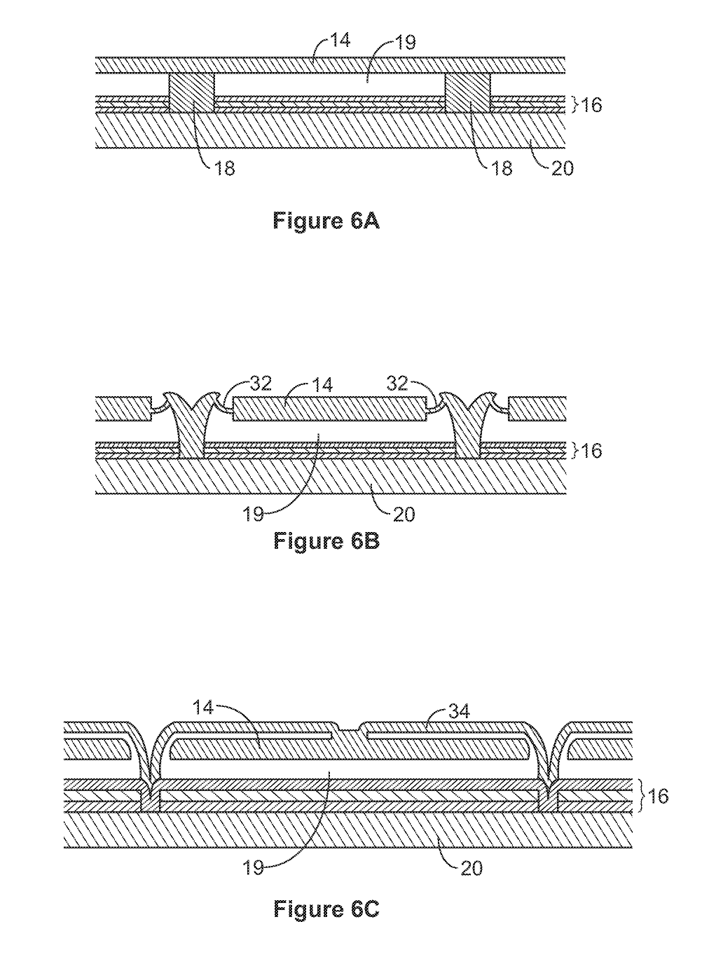

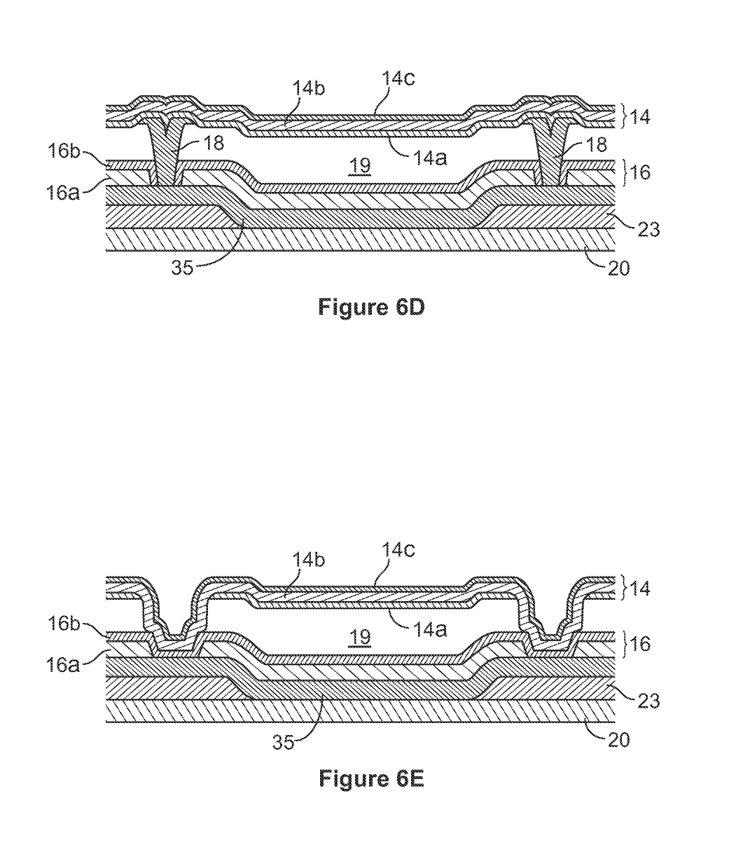

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

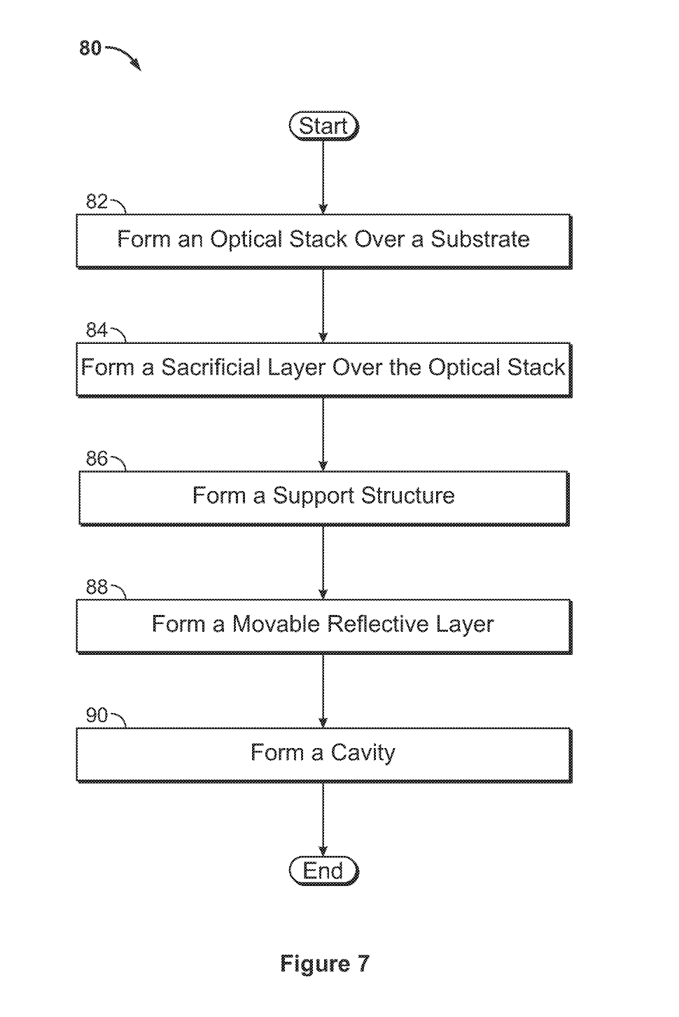

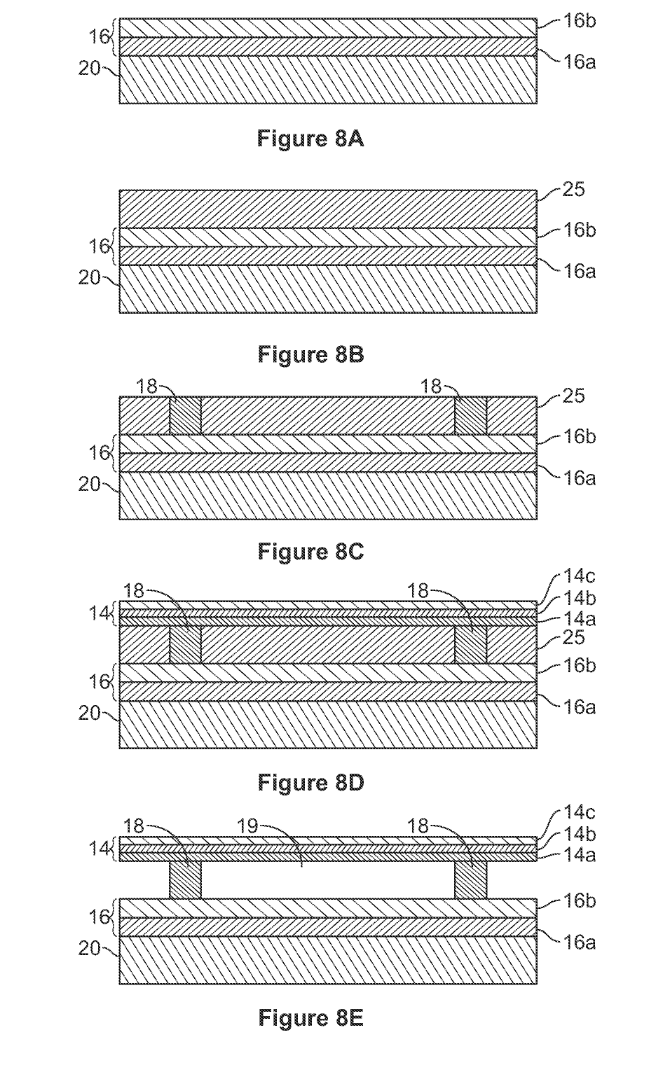

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

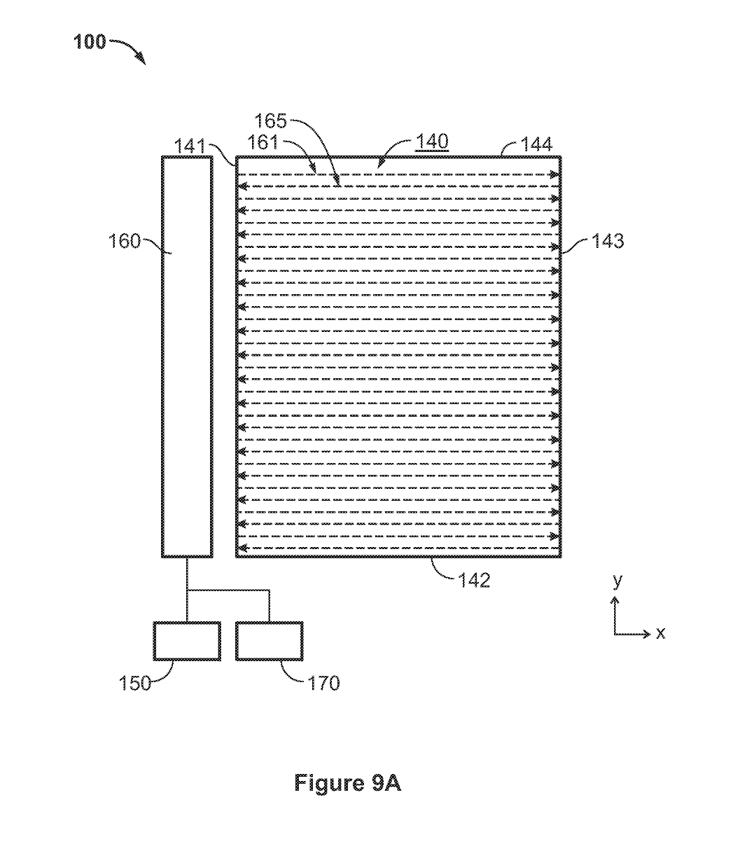

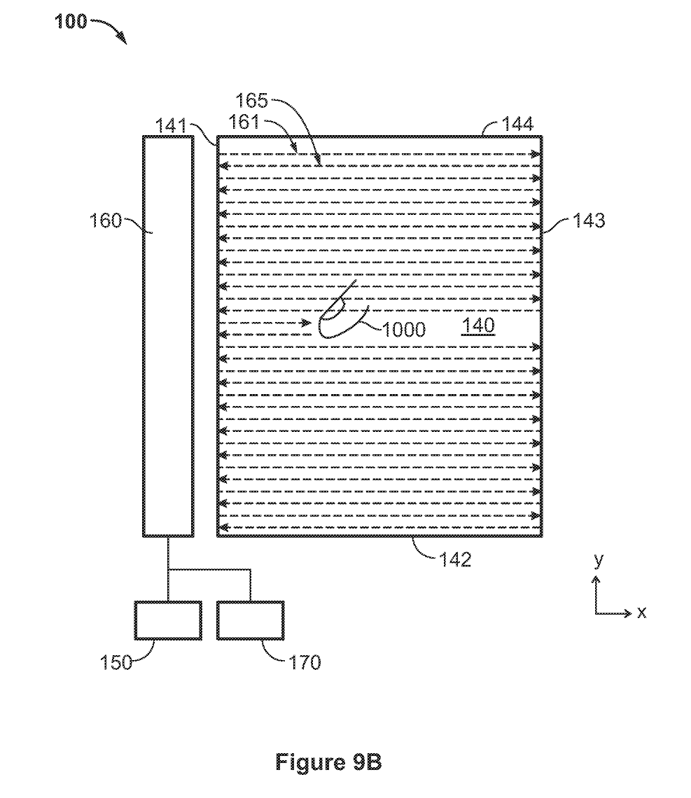

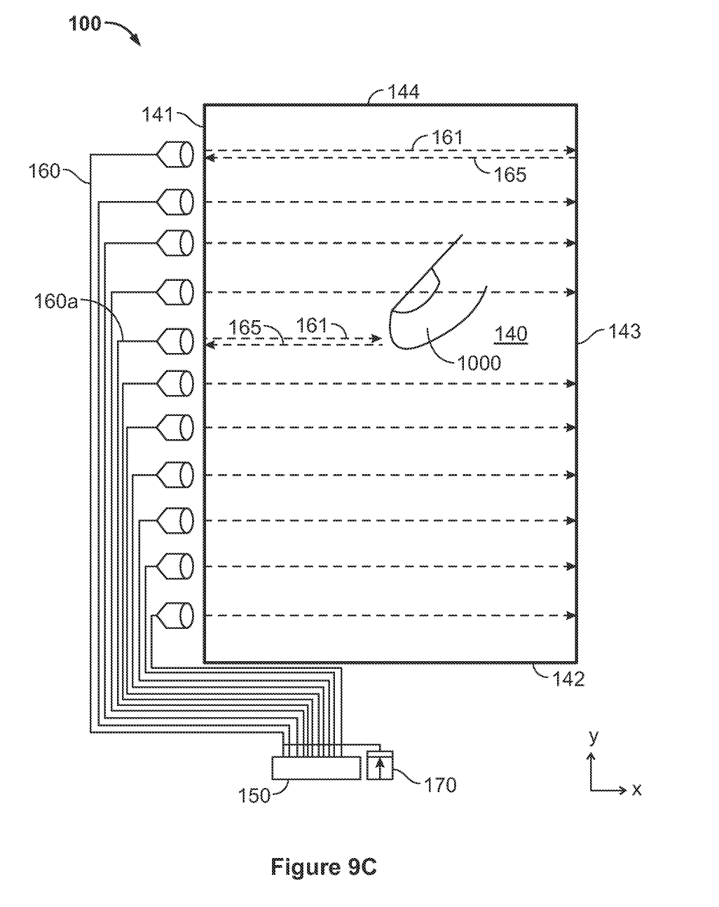

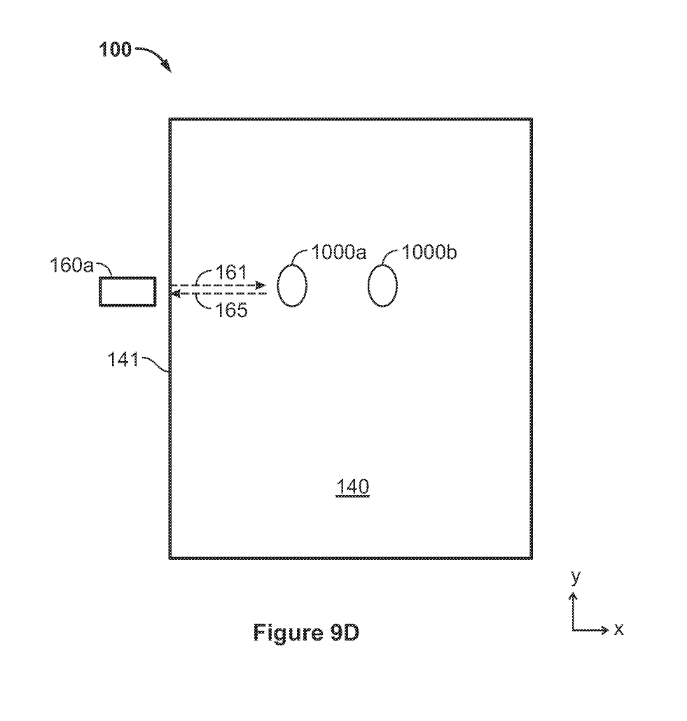

FIGS. 9A-9D schematically illustrate examples of input touch systems. FIG. 9A schematically illustrates an example input touch system 100 compatible with display device 40 described below. The input touch system 100 can be used as the input device 48 described herein. The display device 40 allows, e.g., a user to view different options and functionalities. The input touch system 100 can be implemented to enable the user to select an option viewed on the display device 40. An example application is a touch-sensitive screen, where the user can choose an option by touching the touch-sensitive screen with a reflecting object. The reflecting object could be, for example, a finger or a stylus.

Various implementations of the touch system 100 can determine the user selected option by determining the location of the reflecting object on the touch-sensitive screen. Optical ranging can help determine the location of the reflecting object. For example, optical ranging can measure a distance to a target location by illuminating the target with light or optical signals. Time-of-flight is one such optical ranging technique. Time-of-flight can provide the time between transmitting a light pulse and receiving the returning light pulse reflected from the reflecting object. The time-of-flight can give an indication of the distance to the reflecting object, thus providing at least one of the two coordinates of the location of the reflecting object on the touch-sensitive screen. Some implementations therefore involve a plurality of light or signal paths using at least one light source, at least one light guide, and at least one light detector. More details will be discussed below.

The input touch system 100 includes a surface 140. The surface 140 can be, e.g., a surface of a display such as included in cellular telephones, mobile television receivers, wireless devices, smartphones, bluetooth devices, PDAs, wireless electronic mail receivers, hand-held or portable computers, netbooks, notebooks, smartbooks, tablets, printers, copiers, scanners, facsimile devices, GPS receivers/navigators, cameras and camera view displays, MP3 players, camcorders, game consoles, wrist watches, clocks, calculators, television monitors, flat panel displays, electronic reading devices (e.g., e-readers), computer monitors, stereo systems, cassette recorders or players, DVD players, CD players, VCRs, radios, portable memory chips, or any electronic device as discussed above. In some implementations, the surface 140 can be a surface on other products such as appliances, toys, vehicles including automobiles and aircraft, etc. In some implementations, the surface 140 can be, e.g., a surface on a microwave, refrigerator, washer, dryer, washer/dryers, a kitchen countertop, an automobile dashboard or other auto display (e.g., odometer display, etc.), cockpit controls and/or displays, keypad for home security systems, or any printed surface where a user can input options. The surface 140 may be included on medical, military or manufacturing instruments or equipment and may be used in other applications and be included on other devices as well. The shape of the surface 140 can be, e.g., rectangular, but other shapes, such as square or ovular also can be contemplated. The surface 140 can include a first edge 141 and a second edge 142. The surface 140 also can have other edges, such as a third edge 143 and a fourth edge 144. All the edges can define an area of the surface 140. The first edge 141 and the third edge 143 can be parallel to the y-axis, while the second edge 142 and the fourth edge 144 can be parallel to the x-axis.

In some implementations, the input touch system 100 includes at least one light source 150. The light source 150 can include a plurality of light sources. The light source 150 can be any known light source or a functional equivalent. For example, the light source 150 could be a fluorescent lamp, an incandescent lamp, or a light emitting diode (LED). In some implementations, the light source 150 may operate at visible wavelengths. In some other implementations, the light source 150 may operate at infrared wavelengths because infrared is not visible to the human eye and thus will not cause visible interference.

The input touch system 100 also can include a light guide 160. The light guide 160 can include an array of light guides. In some implementations, the array of light guides can be optically coupled to a single light source 150 and can distribute the light from the single light source 150. The light guide 160 can be made of glass, or plastic, or other similar material.

The light guide 160 can be optically coupled to the light source 150. The light guide 160 can be configured to transmit light from the light source 150 in a direction 161 across the surface 140. For example, the light guide 160 can be positioned along the first edge 141 and the light transmitted from the light guide 160 can travel in a direction 161 substantially parallel to the second edge 142. Alternatively, the light guide 160 can be positioned along the second edge 142 and the light transmitted from the light guide 160 can travel in a direction substantially parallel to the first edge 141.

In some implementations, the light guide 160 spreads the light across most or substantially all of the surface 140 area. The light travels across the surface 140 and is reflected back from the opposite edge 143, in an opposite direction 165 and can be received using the light guide 160.

The input touch system 100 can include at least one optical detector 170 optically coupled to the light guide 160. The optical detector 170 can receive information from the light reflected from the far edge, i.e., edge 143, via the light guide 160. The optical detector 170 can include an array of optical detectors. The optical detector 170 can be a photodetector, or other similar detector. The touch system 100 is configured to receive an input, e.g., a finger, as shown in FIG. 9B and as will be discussed below.

In this implementation, when, e.g., a user touches the surface 140 with a reflecting object 1000, the light in the path of the reflecting object 1000 is interrupted by the reflecting object 1000. A reflecting object can include an object from which at least a portion of light, e.g., even as low as 20%, 10%, 5%, 1% or less, can be reflected as long as some light returns to the optical detector 170, as will be discussed below. The reflecting object may be diffusely reflecting, specularly reflecting, or a combination thereof. For example, a reflecting object can be a finger or a stylus and not necessarily an object with a mirror-like surface. The light in the path of the reflecting object 1000 thus reflects off the reflecting object 1000 and does not reflect off the opposite edge 143 of the surface 140.

In some implementations, the information received by the optical detector 170 can provide the time-of-flight between transmitting the light and receiving the transmitted light reflected back in an opposite direction. For example, when no reflecting object 1000 interrupts the light, the light received using the optical detector 170 provides information on the time-of-flight between transmitting the light and receiving the transmitted light reflected from the opposite edge 143. When a reflecting object 1000 interrupts a path of light, the light received using the optical detector 170 can provide information regarding the time-of-flight between transmitting the light and receiving the transmitted light that is reflected from the reflecting object 1000. The time-of-flight will be shorter when the reflecting object 1000 interrupts the path of light. Numerous pulses are emitted, for example, each second, and their return is monitored by the detector. In some implementations, for example, the update rate of transmitting, e.g., light pulses, can be on the order of milliseconds (e.g., 1 to 10 milliseconds). In some implementations, the input touch system 1000 includes circuitry and electronics for time-of-flight calculations.

The time-of-flight of the transmitted light and the light reflected from the reflecting object 1000 can provide information on the location of the reflecting object 1000 along one of the two orthogonal directions, e.g., the x or y direction. For example, the time-of-flight of the transmitted light and the reflected light can be translated into a distance between the reflecting object 1000 and the optical detector 170. This distance can provide either the x or y coordinate of the reflecting object 1000 on the surface 140. In FIG. 9B, the time-of-flight between the transmitted light and the light reflected from the reflecting object 1000 can be translated into a distance on the surface 140 in the x direction. In some implementations, the time-of-flight between the far edge 143 and the optical detector 170 can provide a calibration as to the location of the far edge 143.

The location of the reflecting object 1000 on the surface 140 in the other orthogonal direction can be determined by identifying a position or relative position where the light guide structure 160 receives the reflected light. For example, the optical detector 170 can include a plurality of detectors (not shown) with each detector corresponding to a location along the light guide structure 160. In FIG. 9B, each detector can correspond to a vertical location, e.g., a y coordinate, along the light guide 160. Identifying a position can include identifying which detector received the reflected light. In some implementations, the light guide structure 160 includes a plurality of light guides; and identifying a position can include identifying which light guide received the reflected light as will be discussed in relation with FIG. 9C.

FIG. 9C illustrates an example input touch system 100, where the light guide 160 includes a plurality of light guides, e.g., 160a. In some implementations, the apertures of the plurality of light guides are spaced approximately evenly apart along an edge, e.g., along the first edge 141, such that the light guide 160 spreads the light across most or substantially all of the surface 140 area. As explained for FIG. 9B, the light in the path of the reflecting object 1000 reflects off the reflecting object 1000. The light guide 160a in the path of the reflecting object 1000 receives the light reflected from the reflecting object 1000. The optical detector 170 can receive information from the light reflected from the reflecting object 1000 via the light guide 160a.

In some implementations, at least one lens (not shown) can be positioned on an end of the light guide 160. In implementations with a plurality of light guides, lenses can be positioned on the ends of each of the plurality of light guides. The lenses can be configured to substantially collimate the light in a substantially straight and narrow beam so that a portion of light reflected back from the reflecting object 1000 is directed straight as it travels back into the same aperture of the light guide 160a that transmitted the light beam. The amount of collimation can be such that enough of the reflected light can be detected by the optical detector 170. Additionally, the amount of collimation can depend on the spacing between each adjacent light guide and on the width or length of the surface 140. The numerical aperture of the light guide will reduce the amount of stray light incident on the light guide at large angles that is collected by the light guide. In some implementations, additional features may be used to control the acceptance angle of the light guide 160a and to block stray light scattered randomly off the reflecting object 1000 such as but not limited to using a light baffle or lens with a small numerical aperture.

In some implementations, the light not in the path of the reflecting object 1000 may reflect off the opposite edge 143 of the surface 140. In these implementations, the light guides that are not in the path of the reflecting object 1000, e.g., those other than 160a, may receive the light reflected from the opposite edge 143, and may send the information from the reflected light to the optical detector 170. This information can provide calibration as to the location of the far edge, e.g., 143.

The location of the reflecting object 1000 on the surface in one orthogonal direction can be determined by the time-of-flight of the transmitted light and the reflected light as described above. The location of the reflecting object 1000 on the surface 140 in the other orthogonal direction can be determined by a known position along the edge in that orthogonal direction, e.g., the known position of the light guide 160a receiving the light reflected from the reflecting object 1000. The vertical position of the end of the light guide 160a along the edge 141 provides the y-coordinate of the reflecting object 1000 in FIG. 9C.

The implementation in FIG. 9C shows light transmitted in one direction 161. In this implementation, the location of any reflecting object 1000 on the surface 140 can be determined so long as it is not blocked by another object in the same path of light. Thus, the input touch system 100 can distinguish between two reflecting objects, e.g., two or more fingers touching the display at the same time, on the surface 140 unless the fingers were lined up in the same optical path over which the light is transmitted.

FIG. 9D illustrates an example input touch system 100 with the light guide 160a (the plurality of other light guides are not shown) positioned in accordance with some implementations disclosed herein. In FIG. 9D, two reflecting objects 1000a and 1000b are simultaneously placed on the area of the surface 140. The light guide 160a along the first edge 141 can receive light reflected from the first reflecting object 1000a. However, the light is reflected by the first reflecting object 1000a before it can reach the second reflecting object 1000b, and thus the light guide 160a does not receive light reflected from the second reflecting object 1000b (assuming the first and second reflecting objects 1000a and 1000b are similar in size and the first reflecting object 1000a is opaque). Thus, the optical detector 170 (not shown) can receive information from the light reflected from the first reflecting object 1000a, but does not receive information about the second reflecting object 1000b. Other implementations discussed below can detect the second reflecting object 1000b.

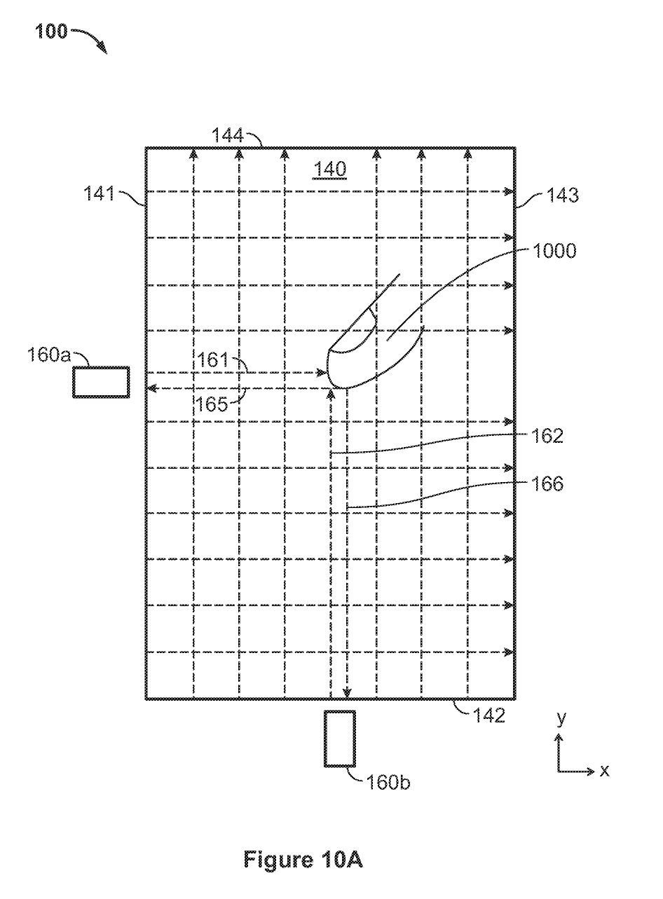

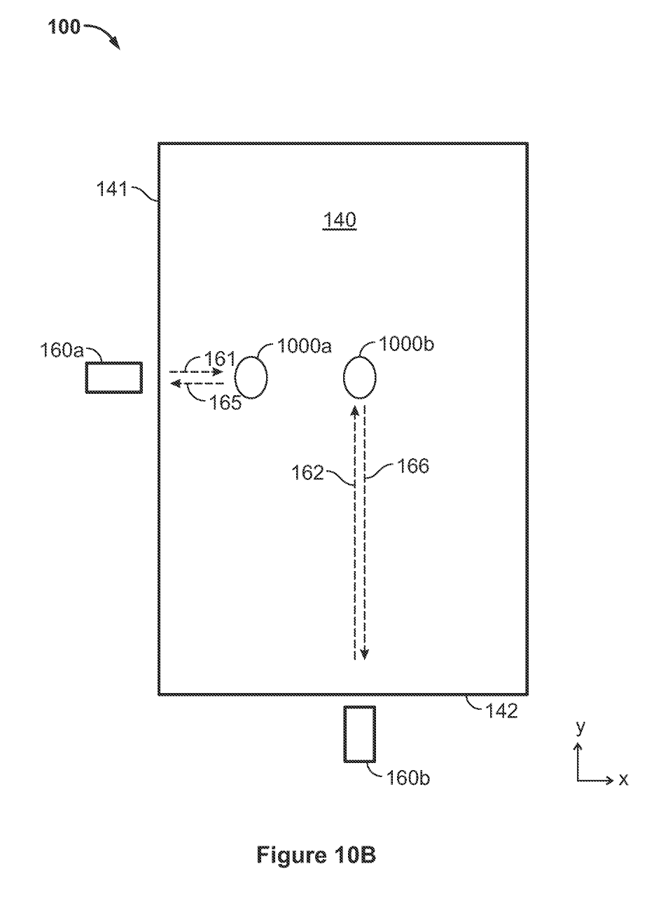

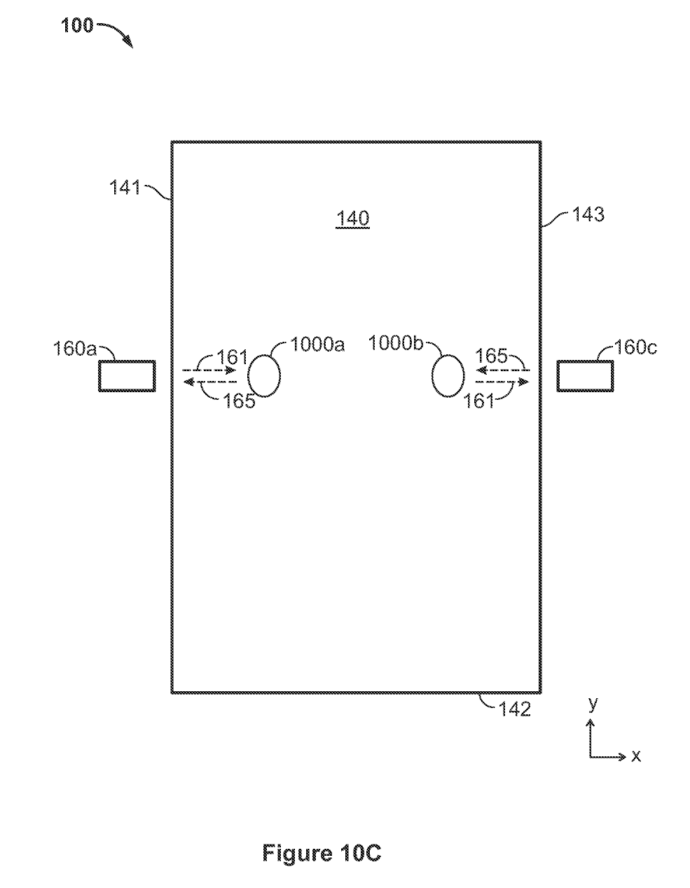

FIGS. 10A-10C schematically illustrate additional examples of input touch systems. The light guide structure 160 can transmit light along at least two directions. For example, the light can be transmitted in directions substantially perpendicular to one another (e.g., as depicted in FIG. 10A). For example, the light can be transmitted in directions about 90 degrees apart, about 89 to about 91 degrees apart, about 88 to about 92 degrees apart, about 87 to about 93 degrees apart, about 86 to about 94 degrees apart, about 85 to about 95 degrees apart, about 84 to about 96 degrees apart, about 83 to about 97 degrees apart, about 82 to about 98 degrees apart, about 81 to about 99 degrees apart, or about 80 to about 100 degrees apart. Other arrangements and orientations outside theses ranges are also possible. FIG. 10A schematically illustrates an example input touch system 100 that is similar to FIG. 9C, except that not only are the ends of the plurality of light guides (only light guide 160a is shown) positioned along the first edge 141 such that light travels across the surface 140 in a first direction 161, but also, the ends of the light guides (only light guide 160b is shown) are also positioned along the second edge 142 such that light travels across the surface 140 in a second direction 162. In some implementations, the first direction 161 can be substantially parallel to the second edge 142, and the second direction 162 can be substantially parallel to the first edge 141.

When, e.g., the user does not touch the surface 140, the light travelling in the first direction 161 may be reflected back from the opposite edge 143 in an opposite direction 165, while the light travelling in the second direction 162 may be reflected back from the opposite edge 144 in an opposite direction 166. The light travelling in each of directions 161 (and 165) and 162 (and 166) can be in the same or different planes.

When a reflecting object 1000 touches the surface 140, the light in the light path of the reflecting object 1000 reflects off the reflecting object 1000 and does not reflect off the opposite edges 143 and 144. For example, when the light guide 160a transmits light in a first direction 161 and the light contacts the reflecting object 1000, the light reflects in an opposite direction 165. The reflected light can be received by the light guide 160a. The light guide 160b can transmit light in a second direction 162 and the reflecting object 1000 can reflect the light in an opposite direction 166, which can be received by the light guide 160b.

The optical detector 170 (not shown) can receive information from the light reflected from the reflecting object 1000. In some implementations, the optical detector 170 also can receive information from the light reflected from the opposite edges 143 and 144. The location of the reflecting object 1000 on the surface 140 can be determined by the time-of-flight measurement of the light transmitted through the light guide 160a and reflected from the reflecting object 1000 back through the light guide 160a (e.g., providing the x-coordinate) and by the vertical position of the light guide 160a along the edge 141 (e.g., providing the y-coordinate). Alternatively, the location of the reflecting object 1000 on the surface 140 can be determined by the horizontal position of the light guide 160b along the edge 142 (e.g., providing the x-coordinate) and the time-of-flight measurement of the light transmitted through the light guide 160b and reflected from the reflecting object 1000 back through the light guide 160b (e.g., providing the y-coordinate). Therefore, as shown in FIG. 10A, the information provided to the optical detector 170 in the input touch system 100 can be redundant based on a single touch. However, this implementation can disambiguate or distinguish two touches lined up in the same, e.g., horizontal or vertical, path along which the light beam travels as explained below with reference to FIG. 10B.

FIG. 10B schematically illustrates an example input touch system 100 with the light guide 160a positioned along the first edge 141 to receive light reflected from the first reflecting object 1000a. The optical detector 170 (not shown) can receive reflected light from the first reflecting object 1000a through the light guide 160a. The time-of-flight measurement of the light transmitted through light guide 160a can provide information regarding the x-coordinate of the reflecting object 1000a and the vertical position of the light guide 160a along the edge 141 can provide information regarding the y-coordinate of the reflecting object 1000a. However, the light guide 160a may not receive light from the second reflecting object 1000b. Thus, the optical detector 170 (not shown) may not be able to receive information about the second reflecting object 1000b via the light guide 160a, as was the case with the implementation in FIG. 9D. However, the light guide 160b along the second edge 142 can receive light reflected from the second reflecting object 1000b. Thus, the optical detector 170 (not shown) optically coupled to the light guide 160b can receive information regarding the second reflecting object 1000b. The location of the reflecting object 1000b on the surface 140 can be determined by the horizontal position of the light guide 160b along the edge 142 (e.g., providing the x-coordinate) and the time-of-flight measurement of the light transmitted and returning to the light guide 160b (e.g., providing the y-coordinate).

FIG. 10C schematically illustrates another example input touch system 100. In some implementations, where the light is transmitted in directions opposite each other, as depicted in FIG. 10C, the input touch system 100 can disambiguate two touches lined up in the same path of light. The ends of the light guides 160a and 160c can be positioned along the first edge 141 and along the opposite edge 143, respectively. The light guide 160a can receive the light reflected from the reflecting object 1000a and the optical detector 170 (not shown) can receive information regarding the location of the reflecting object 1000a. Thus, the information received by the light reflected through the light guide 160a provides the location of the first reflecting object 100a by the time-of-flight information from the light reflected from the reflecting object 1000a (e.g., providing the x-coordinate) and by the vertical position of the light guide 160a along the edge 141 (e.g., providing the y-coordinate).

Similar to the implementation in FIG. 9D, the optical detector 170 may not be able to receive information regarding reflecting object 1000b from the light guide 160a. However, in this implementation, light guide 160c can transmit light in a direction 165 opposite the direction 161. The light can reflect from the reflecting object 1000b in the direction 161. The light guide 160c can receive the reflected light and the optical detector 170 (not shown) can receive information regarding the location of the reflecting object 1000b. For example, the x-coordinate can be provided by the time-of-flight information from the light reflected from the reflecting object 1000b and the y-coordinate can be provided by the vertical position of light guide 160c along the edge 143.

In some implementations, methods to prevent the light guide 160c from receiving transmitted light from light guide 160a, e.g., when no reflecting object 1000 is introduced, can be used. For example, the light guides 160a and 160c can transmit light out of phase from one another, can operate with different wavelength ranges, or can be positioned such that the transmitted light is not pointing into the other. In some implementations, the lenses associated with the light guides 160a and 160c can substantially collimate the light to decrease the amount of light that is directed into the other light guide. Other techniques also may be used and a combination of techniques may be employed in some implementations.

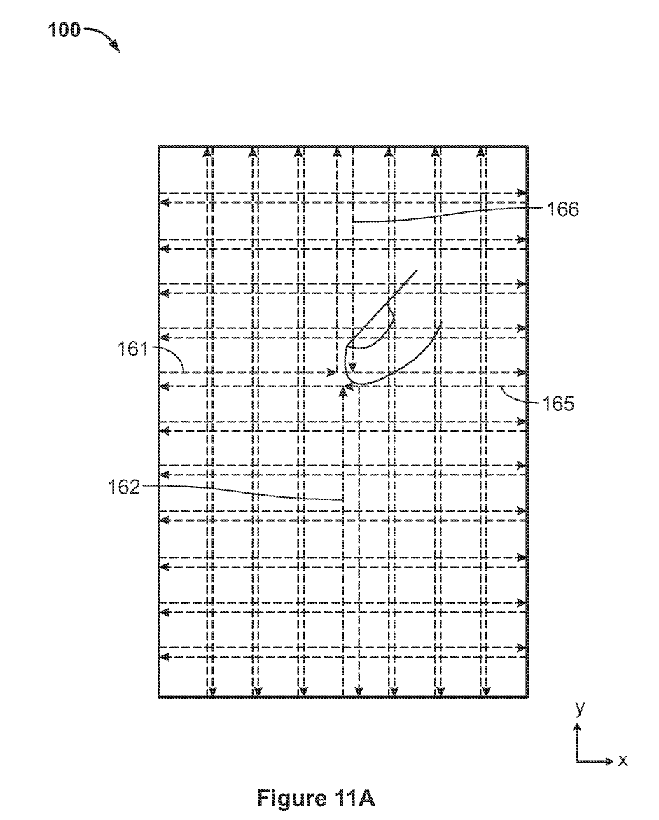

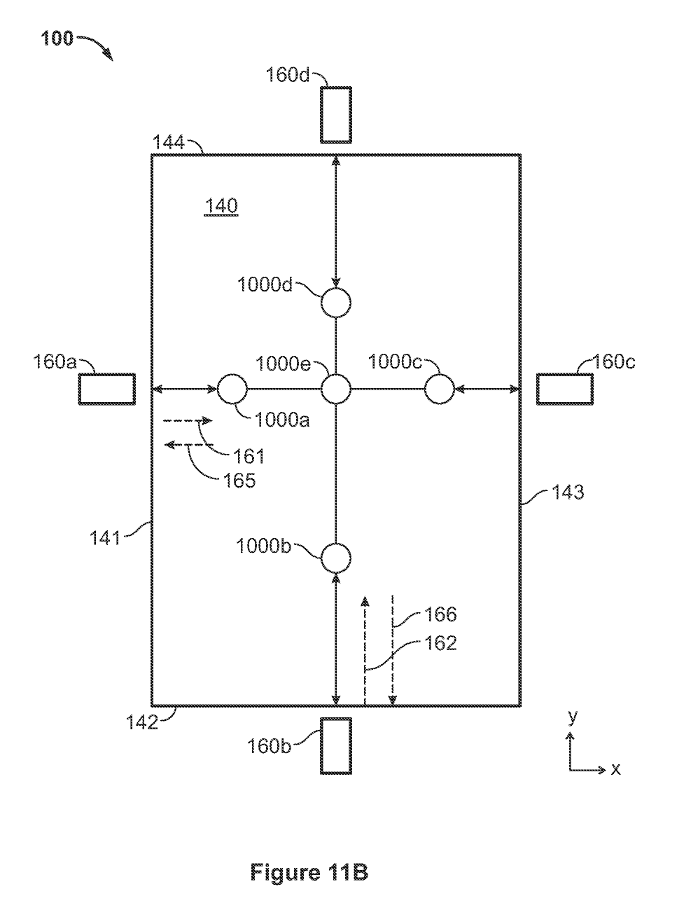

FIGS. 11A and 11B schematically illustrate additional examples of input touch systems. FIG. 11A schematically illustrates an example input touch system 100 where the light guides are configured to transmit light in four directions. In this implementation, the ends of the light guides (not shown) are positioned such that light is transmitted in directions 161, 162, 165 and 166. FIG. 11B schematically illustrates the example input touch system 100 of FIG. 11A where four reflecting objects 1000a, 1000b, 1000c, and 1000d are touching the surface 140 and each touch can be disambiguated. The input touch system 100 can be configured to determine the location of more than one reflecting object 1000 on the area of the surface 140, including identifying two reflecting objects lying along a substantially collinear light beam path. For example, when the light guide 160a transmits light in a direction 161, the light can be reflected from the reflecting object 1000a in an opposite direction 165 and can be received using the light guide 160a. The optical detector 170 (not shown) can be optically coupled to the light guide 160a and can receive information about the reflecting object 1000a. The time-of-flight measurement of the light reflected from the reflecting object 1000a can provide information on the x-coordinate of the reflecting object 1000a and the position of light guide 160a along the edge 141 can provide information on the y-coordinate of the reflecting object 1000a.

The light guide 160b can transmit light in one direction 162 and can receive the light reflected from the reflecting object 1000b in an opposite direction 166. The optical detector 170 can receive the information about the reflecting object 1000b based on the received light. The position of the light guide 160b along the edge 142 can provide information on the x-coordinate of the reflecting object 1000b and the time-of-flight measurement of the light reflected from the reflecting object 1000b provides information on the y-coordinate of the reflecting object 1000b.

Light can be transmitted by the light guide 160c in one direction 165 and can be reflected by the reflecting object 1000c in an opposite direction 161. The information from the light reflected from the reflecting object 1000c can be received by the optical detector 170. The time-of-flight measurement of the light reflected from the reflecting object 1000c can provide information on the x-coordinate of the reflecting object 1000c and the position of the light guide 160c along the edge 143 can provide information on the y-coordinate of the reflecting object 1000c.

Light can be transmitted by the light guide 160d in one direction 166 and can be reflected by the reflecting object 1000d in an opposite direction 162. The optical detector 170 can receive information from the light guide 160d. The position of the light guide 160d along the edge 144 can provide information on the x-coordinate of the reflecting object 1000d and the time-of-flight measurement of the light reflected from the reflecting object 1000d can provide information on the y-coordinate of the reflecting object 1000d.

In the implementation shown in FIG. 11B, five or more touches can be disambiguated, as long as a touch is not hidden by four other touches. For example, in the case of five touches, one unlikely configuration exists in which the fifth touch might not be readily identified. The touch by a reflecting object 1000e in the middle of the cross pattern might be hidden by the four other touches 1000a, 1000b, 1000c, and 1000d. In instances where the touches are momentary, e.g., tapping with a stylus, the possibility of five touches is unlikely. However, in instances where the touches slide over the surface, e.g., writing with a stylus or multiple players moving objects in a game, more than five touches are possible. In some implementations, tracking can be used to locate the hidden touch 1000e. For example, some implementations can track the motion vector associated with a touch. The technique can interpolate where the next touch would be. If, e.g., the interpolated location is at or near an intersection of four other touches and the touch was not detected, some implementations can guess that a fifth touch occurred at the hidden location.

In some implementations as discussed above for FIG. 9C, at least one lens can be positioned on an end of at least one light guide 160. In implementations with a plurality of light guides, lenses can be positioned on the ends of each of the plurality of light guides 160. The lenses can be configured to substantially collimate the light in a substantially straight and narrow beam so that a substantial portion of the light reflected from the reflecting object 1000 is directed straight back into the same aperture of the light guide 160 that transmitted the light beam. Also as discussed above, structures and methods (e.g., baffles, reduced numerical apertures, etc.) can be implemented to reduce and/or avoid the signal noise and cross-talk introduced by light scattering randomly off an object.

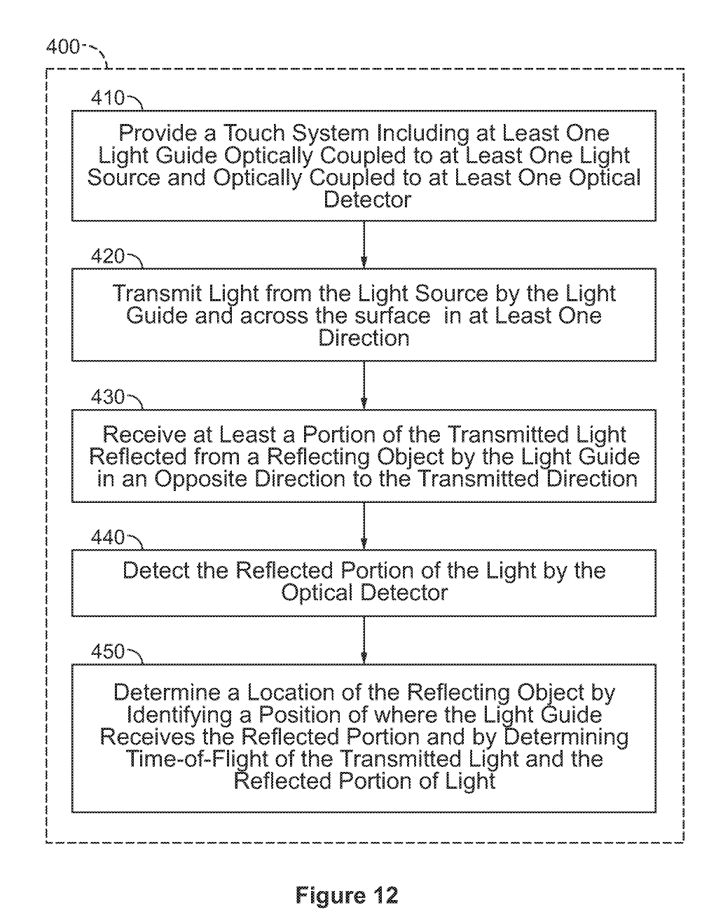

FIG. 12 shows an example method 400 for determining a location of at least one reflecting object 1000 on a surface 140. In some implementations, the method 400 is compatible with the input touch systems 100 described in FIGS. 9A-11B. The surface 140 can have a first edge 141, a second edge 142, and an area between the edges. At block 410, an input touch system 100 is provided. The input touch system 100 can include at least one light guide 160 optically coupled to at least one light source 150 and optically coupled to at least one optical detector 170. The method 400 further includes transmitting light from the light source 150 by the light guide 160 and across the surface in at least one direction 161, as shown in block 420. The method 400 also includes receiving at least a portion of the transmitted light reflected from the reflecting object 1000 by the light guide 160 in an opposite direction 165 to the transmitted direction 161, as shown in block 430. In block 440, the method 400 includes detecting the reflected portion of light by the optical detector 170. The method 400 further includes determining the location of the reflecting object 1000 by identifying the position of where the light guide 160 receives the reflected portion and by determining the time-of-flight measurement of the transmitted light and the reflected portion of the light, as shown in block 450.

The method 400 can further include substantially collimating the transmitted light in a substantially non-divergent path such that the reflected portion returns in a substantially straight path into a same aperture of the light guide that transmitted the light. In some implementations, the light guide structure 160 includes a plurality of light guides. In these implementations, identifying a position in block 450 can include identifying the position or relative position of the light guide 160a receiving the reflected portion. In some other implementations, the optical detector 170 can include a plurality of detectors. In these implementations, identifying a position in block 450 can include identifying the position or relative position of the detector receiving the reflected portion.

In some implementations, the transmitting light block 420 can include transmitting light along at least two directions. The two directions can be opposite each other or substantially perpendicular to each other. In addition, the transmitting light block 420 can include transmitting light along four directions. In some implementations, the locations of more than one reflecting object 1000 can be determined on the area of the surface 140. The locations could lie along the same, substantially similar, or substantially collinear optical path over which the light beam is directed.

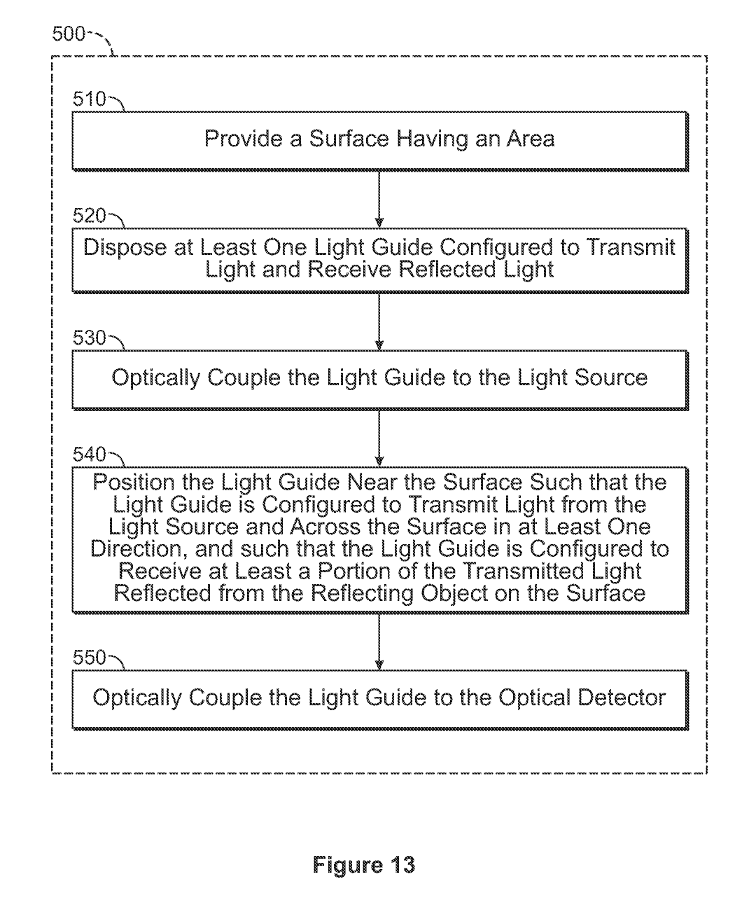

FIG. 13 shows an example method of fabricating a touch system. The method 500 can include providing a surface 140 having an area, disposing at least one light guide 160 configured to transmit light and receive reflected light, and optically coupling the light guide 160 to the light source 150. As shown in block 540, the example method 500 includes positioning the light guide 160 near the surface 140 such that the light guide 160 is configured to transmit light from the light source 150 and across the surface 140 in at least one direction 161, and such that the light guide 160 is configured to receive at least a portion of the transmitted light reflected from the reflecting object 1000 on the surface 140. The method 500 also includes optically coupling the light guide 160 to the optical detector 170 as shown in block 550. The touch system is configured to determine a location of the reflecting object 1000 on the surface 140 by identifying a position where the light guide 160 receives the reflected portion from the reflecting object 1000 and by determining the time-of-flight of the transmitted light and the reflected light. The method 500 also can include providing electronics configured to determine the location of the reflecting object 1000 on the surface 140.

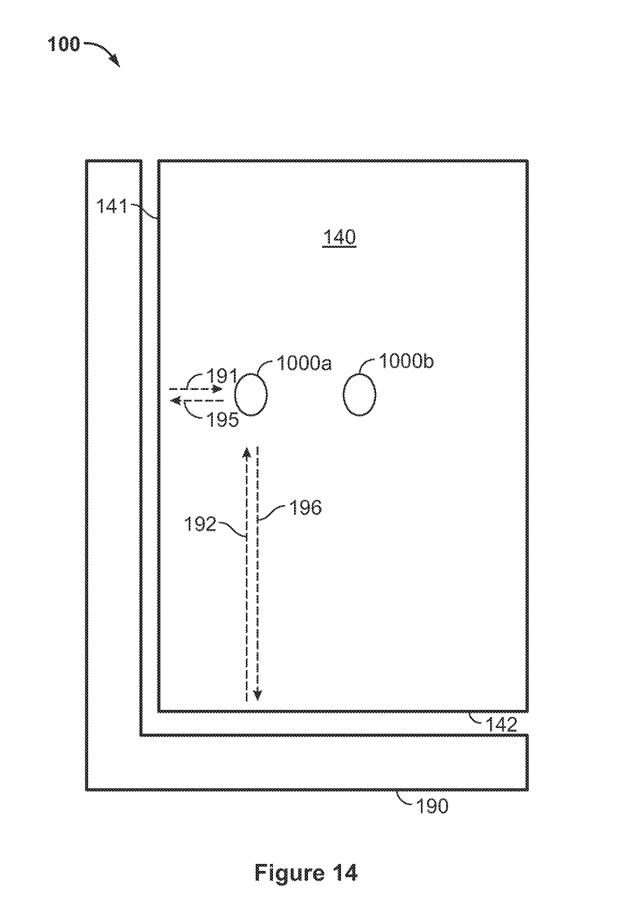

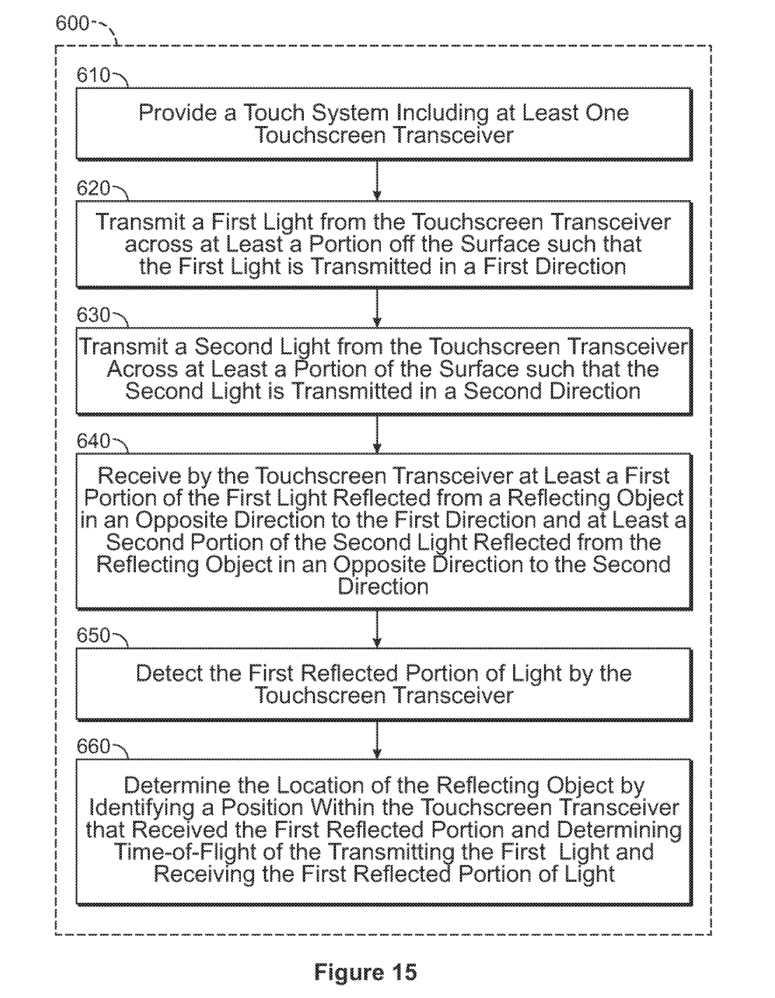

FIG. 14 schematically illustrates an example of an input touch system. The input touch system 100 can include a surface 140 and at least one touchscreen transceiver 190. The touchscreen transceiver may include a transmitter such as a light emission system for outputting light and a receiver such as a light detection system for detecting an optical signal and sensing variations (e.g., amplitude, frequency, etc.) therein. In some implementations, the touchscreen transceiver 190 can include an array of light guides, at least one light source, and at least one detector. In some other implementations, the touchscreen transceiver 190 can include a single light guide, at least one light source, and an array of detectors. The light source can include a plurality of light sources. The light source may operate at visible wavelengths or at infrared wavelengths because infrared is not visible to the human eye and thus will not cause visible interference. The surface 140 can have a first edge 141 and a second edge 142. The shape of the surface 140 can be, e.g., rectangular, but other shapes, such as square or ovular also can be contemplated. The touchscreen transceiver 190 can be configured to transmit an optical signal across the surface 140 such that the optical signal travels in a first direction 191 and in a second direction 192. The first direction 191 and the second direction 192 can be substantially parallel to either the first edge 141 or the second edge 142, or both. The touchscreen transceiver 190 can be configured to receive at least a first portion of the optical signal reflected in an opposite direction 195 to the first direction 191 and at least a second portion of the optical signal reflected in an opposite direction 196 to the second direction 192. In some implementations, the first portion and the second portion are reflected in response to at least one reflecting object 1000a on the surface 140.

The touchscreen transceiver 190 also can be configured to determine a location of the reflecting object 1000a on the surface 140 by identifying the position within the touchscreen transceiver 190 that received the first reflected portion (e.g., identifying within an array of detectors, which detector received the reflected portion of optical signal or identifying with a plurality of light guides, which light guide received the reflected portion of optical signal and by determining time-of-flight of the transmitted optical signal and the first reflected portion of the optical signal. For example, determining the time-of-flight measurement between the transmitted optical signal and the first reflected portion can provide a coordinate along an orthogonal axis (e.g., x-axis) and identifying the position within the touchscreen transceiver 190 that received the first reflected portion can provide the other coordinate along the orthogonal axis (e.g., y-coordinate). Alternatively, identifying the position within the touchscreen transceiver 190 that received the second reflected portion can provide a coordinate along the orthogonal axis (e.g., x-coordinate) and determining the time-of-flight measurement between the transmitted light and the second reflected portion can provide the other coordinate along the orthogonal axis (e.g., y-axis).

As shown in FIG. 14, the first direction and the second direction can substantially perpendicular to one another. Alternatively, the first direction and the second direction can be opposite one another. In some implementations, the touchscreen transceiver 190 can be configured to transmit an optical signal in a third direction 195 and/or a fourth direction 196.

In some implementations, the input touch system 100 can be configured to determine locations of more than one reflecting object, e.g., 1000a and 1000b, on the surface 140. In some implementations, the reflecting objects 1000a and 1000b can be positioned along a substantially similar or collinear optical path for optical signal transmitted from the touchscreen transceiver 190, for example, along a substantially similar or collinear optical path in either the first direction or the second direction. A location of a second reflecting object can be determined by a position within the touchscreen transceiver that received the second reflected portion and the time-of-flight measurement of the second transmitted optical signal and the second reflected portion. Transmitting in the first and second directions can occur at substantially the same time.

The touchscreen transceiver 190 can include electronics to determine time-of-flight measurements. The touchscreen transceiver 190 also can include at least one lens (not shown). For example, the lens can be positioned on an end of an aperture in the touchscreen transceiver 190 to collimate the optical signal in a straight substantially non-divergent path so that the reflected portion is directed straight as it travels into the same aperture of the touchscreen transceiver 190 that transmitted the optical signal.

FIG. 15 shows an example method 600 for determining a location of at least one reflecting object 1000 on a surface 140. In some implementations, the method 600 can be compatible with the input touch system 100 described in FIGS. 9A-11B and 13. At block 610, an input touch system 100 is provided. In some implementations, the input touch system 100 can include at least one touchscreen transceiver 190. At block 620, a first light (or optical signal) can be transmitted from the touchscreen transceiver 190 across at least a portion of the surface 140 such that the first light (or optical signal) is transmitted in a first direction 191. In block 630, a second light (or optical signal) can be transmitted from the touchscreen transceiver 190 across at least a portion of the surface such that the second light (or optical signal) is transmitted in a second direction 192. In some implementations, the first and second directions can be parallel to either the first edge 141 or the second edge 142, or both. At block 640, the touchscreen transceiver 190 can receive at least a first portion of the first light (or optical signal) reflected from the reflecting object 1000 in an opposite direction 195 to the first direction 191 and at least a second portion of the second light (or optical signal) reflected from the reflecting object 1000 in an opposite direction to the second direction. At block 650, the first reflected portion of light (or optical signal) can be detected by the touchscreen transceiver 190. At block 660, the location of the reflecting object 1000 can be determined by identifying a position within the touchscreen transceiver 190 that received the first reflected portion and by determining the time-of-flight of the first transmitted light (or optical signal) and the first reflected portion of the light (or optical signal).

In the method 600, the first and second directions, 191 and 192, can be opposite each other or substantially perpendicular to each other. Transmitting a first light (or optical signal) in block 620 and transmitting a second light (or optical signal) in block 630 can occur at substantially the same time. In some implementations, the transmitting a second light (or optical signal) 630 block can include transmitting light (or optical signals) along four directions. In some implementations, the locations of more than one reflecting object 1000 on the surface 140 can be determined. The locations can lie along a substantially similar or collinear optical path, for example, along the same optical path in either the first direction or the second direction.

The touchscreen described herein can be used in conjunction with a wide variety of displays and display technologies. In some implementations, for example, the touchscreen is used in conjunction with an array of interferometric modulators that form an interferometric modulator display.

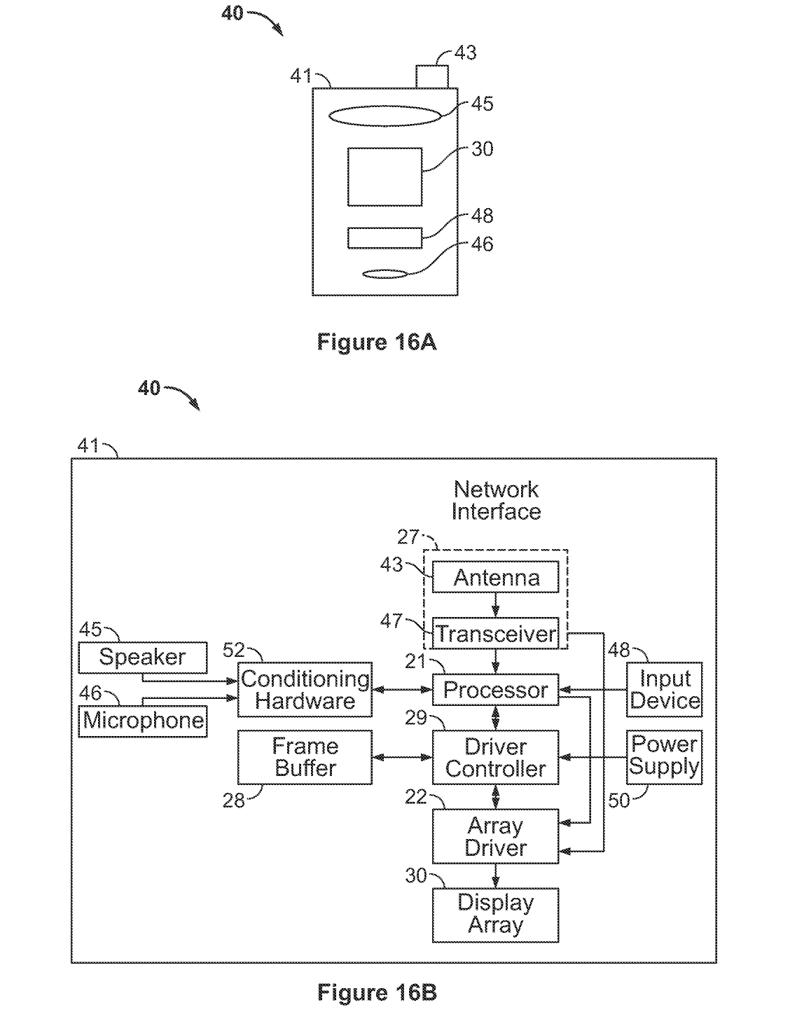

FIGS. 16A and 16B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A touch system comprising:
a surface having an area;
at least one light source;
at least one light guide optically coupled to the at least one light source, the at least one light guide configured to transmit light from the at least one light source such that the light travels across the surface in at least one direction, the at least one light guide configured to receive at least a portion of the transmitted light reflected in an opposite direction to the at least one direction in response to at least one reflecting object on the surface; and
at least one optical detector optically coupled to the at least one light guide and configured to receive the reflected portion of the light from the at least one light guide,
wherein the touch system is configured to determine a location of the at least one reflecting object on the surface by identifying a position where the at least one light guide receives the reflected portion and by determining the time-of-flight of the transmitted light and the reflected portion.

2. The touch system of claim 1, wherein the at least one light guide includes a plurality of light guides, and wherein identifying a position includes identifying the position of the light guide receiving the reflected portion.

3. The touch system of claim 1, wherein the at least one optical detector includes a plurality of detectors, and wherein identifying a position includes identifying the position of the at least one optical detector receiving the reflected portion.

4. The touch system of claim 2, wherein the plurality of light guides transmits the light along at least two directions, the at least two directions are opposite each other.

5. The touch system of claim 4, wherein the plurality of light guides transmits the light in four directions.

6. The touch system of claim 1, wherein the touch system is configured to disambiguate locations of a plurality of reflecting objects on the surface, the plurality of reflecting objects lying along a substantially collinear optical path over which the light is transmitted.

7. The touch system of claim 1 further comprising at least one lens positioned on an end of the at least one light guide.

8. The touch system of claim 1, wherein the at least one light source operates at infrared wavelengths.

9. The touch system of claim 1, further comprising:
a plurality of display elements;
a processor that is configured to communicate with the plurality of display elements, the processor being configured to process image data; and
a memory device that is configured to communicate with the processor.

10. The touch system of claim 9, further comprising:
a driver circuit configured to send at least one signal to the plurality of display elements; and
a controller configured to send at least a portion of the image data to the driver circuit.

11. The touch system of claim 9, further comprising:
an image source module configured to send the image data to the processor.

12. The touch system of claim 11, wherein the image source module includes at least one of a receiver, transceiver, and transmitter.

13. The touch system of claim 9, further comprising:
an input device configured to receive input data and to communicate the input to the processor.

14. The touch system of claim 9, wherein at least one of the display elements includes an interferometric modulator.

15. A method of fabricating a touch system, comprising:
providing a surface having an area;
disposing at least one light guide configured to transmit light and receive reflected light;
optically coupling the at least one light guide to at least one light source;
positioning the at least one light guide near the surface such that the at least one light guide is configured to transmit light from the at least one light source across the surface in at least one direction, and such that the at least one light guide is configured to receive at least a portion of the transmitted light reflected from at least one reflecting object on the surface; and
optically coupling the at least one light guide to at least one optical detector;
wherein the touch system is configured to determine a location of the at least one reflecting object on the surface by identifying a position where the at least one light guide receives the reflected portion from the at least one reflecting object and by determining the time-of-flight of the transmitted light and the reflected portion.

16. The method of claim 15, further comprising providing electronics configured to determine the location of the at least one reflecting object on the surface.

17. The method of claim 15, wherein the at least one light guide includes a plurality of light guides, and wherein identifying a position includes identifying the position of the light guide receiving the reflected portion.

18. The method of claim 15, wherein the at least one optical detector includes a plurality of detectors, and wherein identifying a position includes identifying the position of the detector receiving the reflected portion.

19. The method of claim 16, wherein the electronics are configured to disambiguate locations of a plurality of reflecting objects on the area of the surface, the plurality of reflecting objects lying along a substantially collinear optical path over which the light is transmitted.

20. A touch system comprising:
means for emitting light;
means for guiding light to both direct light from the means for emitting light across a surface and to receive reflected light;
means for detecting light; and
means for determining locations of reflecting objects on the surface, wherein the means for determining locations:
identifies positions where the means for guiding receive light reflected from the reflecting objects, and
determines the time-of-flight of the directed light and the light reflected from the reflecting objects.

21. The touch system of claim 20, wherein the means for emitting light includes a light source or the means for guiding light includes a plurality of light guides or the means for detecting light includes a detector or the means for determining locations includes electronics.

22. The touch system of claim 20, wherein the means for guiding light directs the light across the surface in at least two directions.

23. The touch system of claim 20, wherein the means for determining locations disambiguates locations lying along a substantially collinear optical path over which the light is transmitted.

24. The touch system of claim 20, further comprising means for collimating light.

25. The touch system of claim 24, wherein the means for collimating includes at least one lens on the ends of the means for guiding light.

26. A touch system comprising:
a surface having an area; and
at least one touchscreen transceiver;
wherein the touchscreen transceiver is configured to transmit a first optical signal across the surface in a first direction and a second optical signal across the surface in a second direction,
wherein the touchscreen transceiver is configured to receive at least a first portion of the first optical signal reflected in an opposite direction to the first direction and at least a second portion of the second optical signal reflected in an opposite direction to the second direction, the first portion and the second portion reflected in response to at least one reflecting object on the surface, and
wherein the touchscreen transceiver is further configured to determine a location of the at least one reflecting object on the surface by identifying a position within the touchscreen transceiver that received the first reflected portion and by determining a time-of-flight measurement of transmitting the first optical signal and receiving the first reflected portion.

27. The touch system of claim 26, wherein the first direction and the second direction are opposite one another.

28. The touch system of claim 26, wherein the first direction and the second direction are substantially perpendicular to one another.

29. The touch system of claim 26, wherein the touch system is configured to disambiguate locations of a plurality of reflecting objects, the plurality of reflecting objects lying along a substantially collinear optical path over which the first or second optical signal is transmitted.

30. The touch system of claim 26, wherein a location of a second reflecting object is determined by a position within the touchscreen transceiver that received the second reflected portion and the time-of-flight measurement of transmitting the second optical signal and receiving the second reflected portion.

31. The touch system of claim 26, wherein the touchscreen transceiver includes a plurality of light guides, at least one light source, a detector system, and electronics to determine the time-of-flight measurement.

32. The touch system of claim 31, wherein the touchscreen transceiver further includes at least one lens positioned on an end of at least one of the plurality of light guides to substantially collimate the first transmitted optical signal.

33. The touch system of claim 26, wherein the touchscreen transceiver includes a light source operating at infrared wavelengths.

34. The touch system of claim 26, further comprising:
a plurality of display elements;
a processor that is configured to communicate with the plurality of display elements, the processor being configured to process image data; and
a memory device that is configured to communicate with the processor.

35. The touch system of claim 34, further comprising:
a driver circuit configured to send at least one signal to the plurality of display elements; and
a controller configured to send at least a portion of the image data to the driver circuit.

36. The touch system of claim 34, further comprising:
an image source module configured to send the image data to the processor.

37. The touch system of claim 36, wherein the image source module includes at least one of a receiver, transceiver, and transmitter.

38. The touch system of claim 34, further comprising:
an input device configured to receive input data and to communicate the input data to the processor.

39. A touch system comprising:
means for determining a location of at least one reflecting object on a surface, the means for determining a location including:
means for emitting an optical signal;
means for transmitting an optical signal across the surface such that a first optical signal travels in a first direction and a second optical signal in a second direction, the means for transmitting configured to: receive at least a first portion of the first optical signal reflected in an opposite direction to the first direction and at least a second portion of the second optical signal reflected in an opposite direction to the second direction, the first portion and the second portion reflected in response to the at least one reflecting object on the surface;
means for detecting an optical signal; and
means for processing, configured to:
identify a position within the means for transmitting that received the first reflected portion; and
determine a time-of-flight measurement of the transmitted optical signal and the first reflected portion.

40. The touch system of claim 39, wherein the means for determining a location includes at least one touchscreen transceiver.

41. The touch system of claim 39, wherein the means for emitting includes a light source or the means for transmitting includes a plurality of light guides or the means for detecting includes a detector or the means for processing includes electronics.

42. The touch system of claim 39, wherein the first direction and the second direction are opposite each other.

43. The touch system of claim 39, wherein the first direction and the second direction are substantially perpendicular to each other.

44. The touch system of claim 39, wherein the means for transmitting an optical signal transmits the optical signals in four directions.

45. The touch system of claim 39, wherein the means for a determining a location includes means for disambiguating locations of a plurality of reflecting objects on the surface, the plurality of reflecting objects lying along a substantially collinear optical path over which the optical signal is transmitted in either the first direction or the second direction.
